(19) United States
(12) Patent Application Publication
(10) Pub. No.: US 2003/0214330 A1
(43) Pub. Date: Nov. 20, 2003

(54) Phase-locked loop circuit

(75) Inventors: Syouichi Tanigashira, Kagoshima (JP); Hiroshi Baba, Kasugai (JP)

Correspondence Address: ARENT FOX KINTNER PLOTKIN & KAHN, 1050 CONNECTICUT AVENUE, N.W., SUITE 400, WASHINGTON, DC, 20036, US

(73) Assignee: FUJITSU LIMITED

(21) Appl. No.: 10/418,167

(22) Filed: Apr. 18, 2003

(30) Foreign Application Priority Data
May 20, 2002 (JP) 2002-145303

(51) Int. Cl. H03L 7/06

(52) U.S. Cl. 327/156

(57) ABSTRACT

A PLL circuit includes a voltage controlled oscillator (VCO), a phase comparator detecting phase difference between a reference signal and a feedback signal provided from the VCO, an input voltage control unit controlling input voltage to be provided to the VCO according to the phase difference detected by the phase comparator, a switching unit switching a value of the input voltage to be provided to the VCO, and a switching timing control unit controlling a switching timing of the switching unit based on the given reference signal, wherein the VCO controls a frequency of the feedback signal according to the input voltage provided from the input voltage control unit. As a result, the VCO can rapidly make the feedback signal in phase with the reference signal and therefore it is possible to effectively reduce the required lock-up time.

### BACKGROUND OF THE INVENTION

1. Field of the Invention

The present invention relates to a Phase-Locked Loop (PLL) circuit forming a frequency synthesizer, etc., and in particular to a PLL circuit by which it becomes possible to achieve effective reduction in a required lock-up time when switching the lock frequency and to improve the signal-to-noise ratio.

2. Description of the Related Art

The PLL circuit of the type mentioned above is disclosed in Japanese Laid-Open Patent Application number 10-285024 and is shown in FIG. 1. FIG. 1 is a diagram of an overall circuit configuration of the PLL circuit according to the related art.

The PLL circuit according to the related art shown in FIG. 1 is configured as described below. A phase comparator 100 calculates phase difference between a divided frequency fp of a feedback signal provided from a voltage controlled oscillator (VCO) 500 and a reference frequency fr of a reference signal. The phase comparator 100 provides a DOWN signal or an UP signal depending on the calculated phase difference to a charge pump 200. Based on the DOWN signal or the UP signal, delay circuits 301, 302 switch charge pump current to be provided by the charge pump 200 between a predetermined large current and a predetermined small current, after a predetermined set delay time has elapsed. The charge pump 200 is connected to the VCO 500 via a low pass filter (LPF) 400.

Each of the delay circuits 301, 302 are formed by combining a NOT circuit and an AND circuit. The time delayed by the serially connected NOT circuits is set as the predetermined delay time. The charge pump 200 is provided with switching portions 205, 206, which are switched between large constant current generators 201, 203 that provide a predetermined large charge pump current and small constant current generators 202, 204 that provide a predetermined small charge pump current, respectively. These switching portions 205, 206 are switched based on the delay time set in the delay circuits 301, 302.

The following is a description of a lock-up operation when switching the lock frequency in the PLL circuit according to the related art based on the above-mentioned configuration. As an assumption, the number of NOT circuits in order to generate delay time corresponding to the predetermined delay time is calculated at the time of circuit designing, and the delay circuit is manufactured by serially connecting the calculated number of NOT circuits.

When such a PLL circuit manufactured as mentioned above is activated, the DOWN signal or the UP signal according to the phase difference between the reference frequency fr and the divided frequency fp is provided from the phase comparator 100 to the respective delay circuits 301, 302. In the delay circuits 301, 302, the lock/unlock status between the reference frequency fr and the divided frequency fp is detected. Concurrently, the DOWN signal or the UP signal is provided to respective gate terminals of a P-channel MOS 207 and an N-channel MOS 208 of the charge pump 200.

When the unlock status is detected, in other words, when the UP signal or the DOWN signal is provided from the phase comparator 100, the switching portions 205, 206 are switched to the large constant current generators 201, 203 for the predetermined high current (12 mA), by the delay circuits 301, 302, during the predetermined delay time. When the predetermined delay time has elapsed, the switching portions 205, 206 are switched to the small constant current generators 202, 204 for the predetermined low current (4 mA).

Since the low current such as 4 mA is provided right before the lock status, problematic phenomena such as overshooting or undershooting can be effectively reduced.

However, since the PLL circuit according to the related art is configured as mentioned above, the delay time is fixed by the time of delay determined by the element characteristics of the NOT circuit/circuits forming the delay circuits 301, 302. Therefore, the delay time cannot be arbitrarily adjusted according to the operation status or the circuit configuration. In particular, since the characteristics of the delay circuits 301, 302 are typically determined by the switching speed of MOS transistors forming the NOT circuit, the delay time may differ from that established at the time of circuit designing depending on the difference in the characteristics of the MOS transistors.

Further, in the PLL circuit according to the related art, a good circuit characteristic cannot be obtained unless timing (the delay time) for switching the charge pump current between the predetermined large current and predetermined small current to be provided by the charge pump 200 is always optimized taking the lock-up time, the signal-to-noise ratio, and carrier-to-noise ratio characteristics into consideration.

### SUMMARY OF THE INVENTION

The present invention is directed to solve the problems mentioned above, and an object of the present invention is to provide a PLL circuit by which it becomes possible to achieve effective reduction in the required lock-up time and to improve the signal-to-noise ratio.

The PLL circuit according to the present invention comprises a voltage controlled oscillator, a phase comparator detecting phase difference between an external reference signal and a feedback signal provided from the voltage controlled oscillator, an input voltage control unit controlling input voltage to be provided to the voltage controlled oscillator according to the phase difference detected by the phase comparator, a switching unit switching a value of the input voltage to be provided to the voltage controlled oscillator, and a switching timing control unit controlling a switching timing of the switching unit based on the external reference signal, wherein the voltage controlled oscillator controls a frequency of the feedback signal according to the input voltage provided from the input voltage control unit.

According to the present invention, since the input voltage controlled according to the detected phase difference is provided to the voltage controlled oscillator and the value of the input voltage to be provided to the voltage controlled oscillator is switched by the switching unit based on the switching timing determined by the external reference signal, the voltage controlled oscillator can rapidly make the feedback signal in phase with the external reference signal and thus the required lock-up time can be effectively reduced. Therefore, according to the present invention, since the switching timing for switching the value of the input voltage to be provided to the voltage controlled oscillator can be determined by the external reference signal, it is always possible to obtain a stable switching timing. In other words, it is always possible to determine the switching timing in an ideal condition. Thus overshooting/undershooting can be suppressed as much as possible and the required lock-up time can be effectively minimized.

According to the present invention, the switching timing control unit determines the switching timing of the switching unit also based on serial data provided from the exterior, if necessary.

According to the present invention, since the input voltage controlled according to the detected phase difference is provided to the voltage controlled oscillator and the value of the input voltage to be provided to the voltage controlled oscillator is switched by the switching unit based on the switching timing determined by the serial data provided from the exterior, the switching timing can be arbitrarily changed based on the serial data provided from the exterior and the voltage controlled oscillator can rapidly make the feedback signal in phase with the external reference signal, and therefore the required lock-up time can be effectively reduced. Therefore, according to the present invention, since the switching timing for switching the value of the input voltage to be provided to the voltage controlled oscillator can be determined by the serial data provided from the exterior, it is always possible to obtain a stable switching timing. In other words, it is always possible to determine the switching timing in an ideal condition. Thus overshooting/undershooting can be suppressed as much as possible and the required lock-up time can be effectively minimized.

According to the present invention, the PLL circuit may further comprise an impedance adjustment unit adjusting impedance of a low pass filter to be inserted between the input voltage control unit and the voltage controlled oscillator according to the control of the switching timing control unit, if necessary.

According to the present invention, since the switching timing control unit adjusts the impedance of the low pass filter when the input voltage controlled according to the detected phase difference is provided to the voltage controlled oscillator having the value of the input voltage switched by the switching unit based on the switching time, the low pass filter obtains impedance appropriate to the switched input voltage provided from the input voltage control unit to the low pass filter. Therefore, it is possible to perform the lock-up operation more effectively and also it is always possible to obtain a stable switching timing in an ideal condition. Thus overshooting/undershooting can be suppressed as much as possible and the required lock-up time can be effectively minimized.

According to the present invention, the switching timing control unit determines the switching timing into a time before the time when a first phase reversal of the feedback signal with respect to the external reference signal occurs, if necessary.

According to the present invention, since the input voltage controlled according to the detected phase difference is provided to the voltage controlled oscillator and the value of the input voltage to be provided to the voltage controlled oscillator is switched by the switching unit at the switching timing before the time when the first phase reversal of the feedback signal with respect to the external reference signal occurs, the overshooting of the lock-up waveform can be effectively suppressed. Thus the required lock-up time can be effectively reduced and the signal-to-noise ratio can be improved. Therefore, according to the present invention, since the switching timing for switching the value of the input voltage to be provided to the voltage controlled oscillator can be determined so that the switching timing occurs before the time when the first phase reversal of the feedback signal with respect to the external reference signal occurs, it is possible to perform the lock-up operation more effectively and also it is always possible to obtain a stable switching timing in an ideal condition. Thus overshooting/undershooting can be suppressed as much as possible and the required lock-up time can be effectively minimized.

According to the present invention, the switching timing is determined so that the input voltage having a predetermined large value is provided to the voltage controlled oscillator from the beginning of a lock-up operation and the input voltage having a predetermined small value is provided to the voltage controlled oscillator in the vicinity of the end of the lock-up operation.

Therefore, according to the present invention, since the switching timing can be determined so that the input voltage having a predetermined large value is provided to the voltage controlled oscillator from the beginning of the lock-up operation and the input voltage having a predetermined small value is provided to the voltage controlled oscillator in the vicinity of the end of the lock-up operation, it is always possible to obtain a stable switching timing. In other words, it is always possible to determine the switching timing in an ideal condition. Thus overshooting/undershooting can be suppressed as much as possible and the required lock-up time can be effectively minimized.

### BRIEF DESCRIPTION OF THE DRAWINGS

Other objects, advantages, and further features of the present invention will become more apparent as the description proceeds taken in conjunction with the accompanying drawings in which:

FIG. 1 is a diagram of an overall circuit configuration of a PLL circuit according to the related art;

FIG. 2 is a diagram of an overall circuit configuration of a PLL circuit according to a first embodiment of the present invention;

FIG. 3A through FIG. 3C are diagrams for describing various outputs from a phase comparator in the PLL circuit according to the first embodiment of the present invention;

FIG. 4 is a detailed circuit diagram of a timer circuit in the PLL circuit according to the first embodiment of the present invention;

FIG. 5 is a diagram showing examples of switching time of the timer circuit set in the PLL circuit according to the first embodiment of the present invention;

FIG. 6 is a diagram of an overall circuit configuration of the PLL circuit according to a second embodiment of the present invention;

FIG. 7 is a diagram of an overall circuit configuration with a modification of the PLL circuit according to the second embodiment of the present invention; and

FIG. 8 is a graph illustrating the change in frequency of a PLL circuit according to another embodiment of the present invention.

### DETAILED DESCRIPTION OF THE PREFERRED EMBODIMENTS

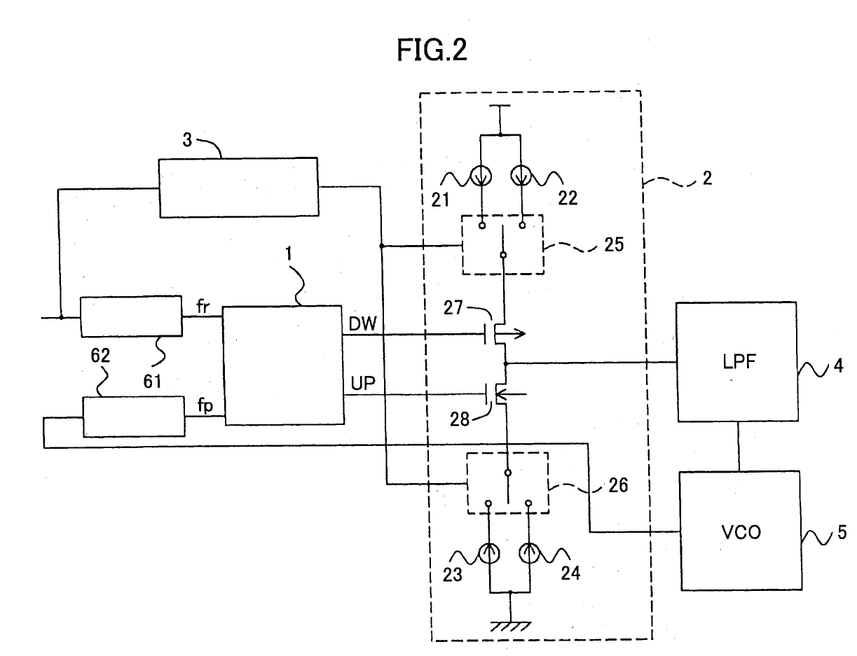

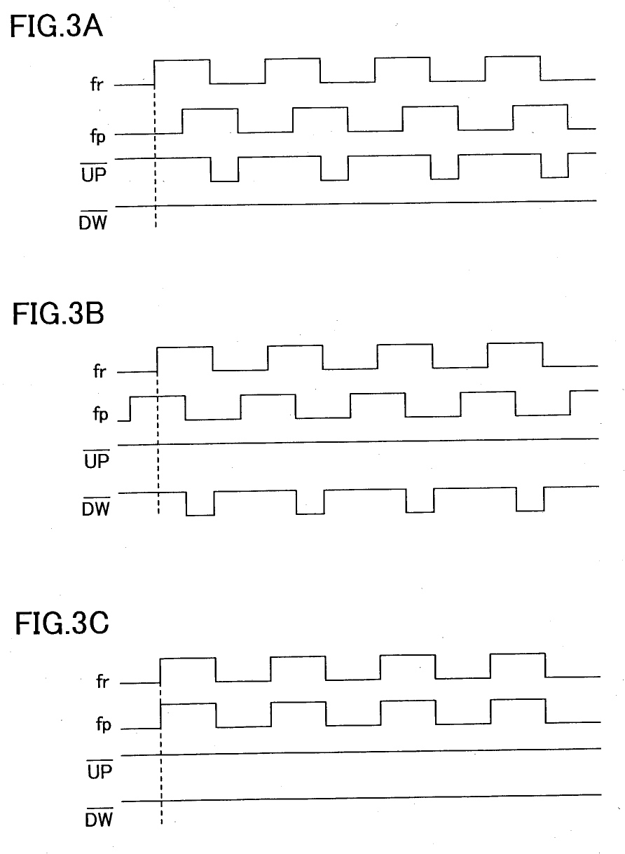

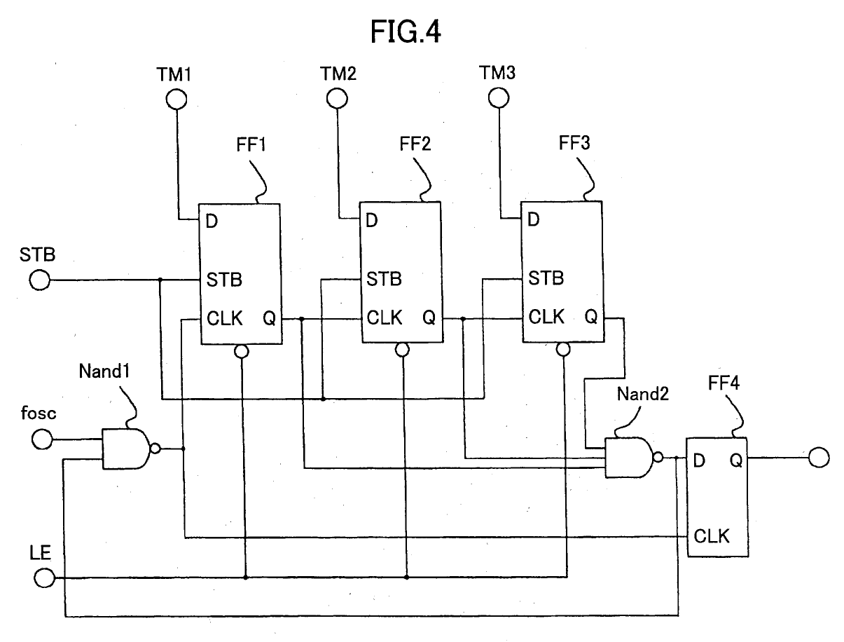

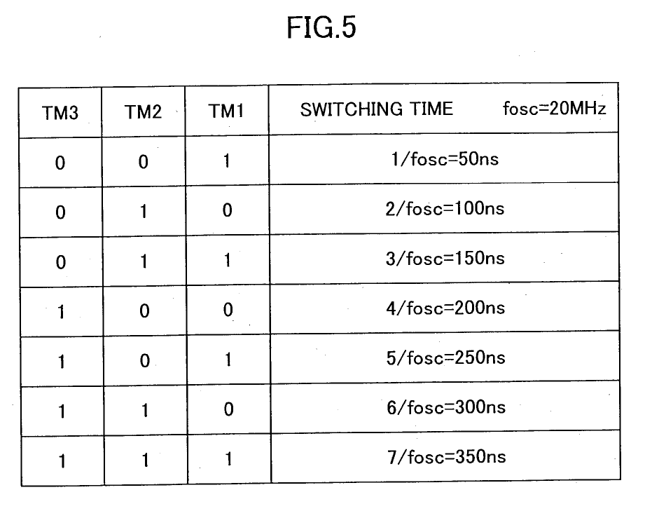

A description of the PLL circuit according to the first embodiment of the present invention is given hereinafter with reference to FIG. 2 through FIG. 5. FIG. 2 is a diagram of an overall circuit configuration of the PLL circuit according to the first embodiment. FIG. 3A through FIG. 3C are diagrams for describing various outputs from a phase comparator in the PLL circuit according to the first embodiment. FIG. 4 is a detailed circuit diagram of a timer circuit in the PLL circuit according to the first embodiment. FIG. 5 is a diagram showing examples of switching time of the timer circuit set in the PLL circuit according to the first embodiment.

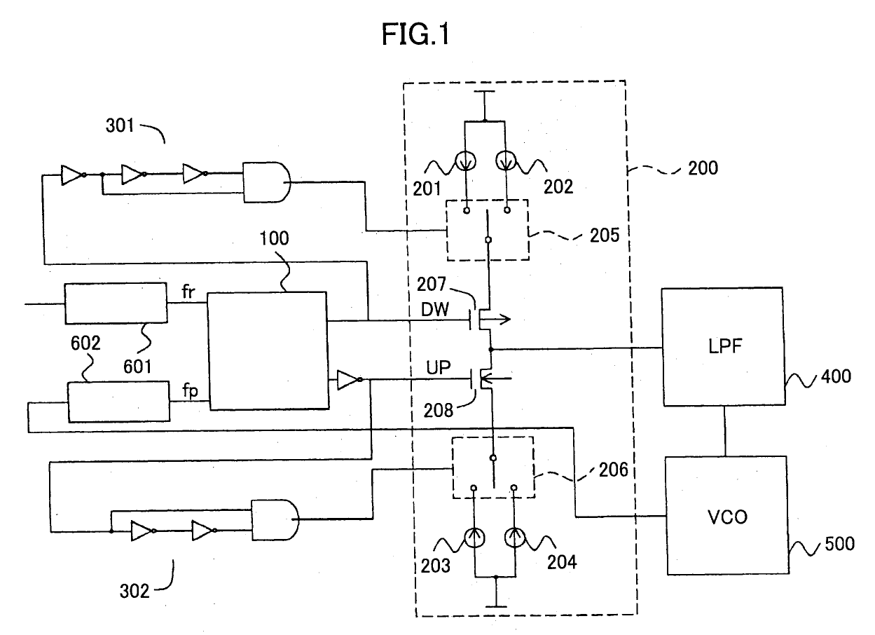

The PLL circuit according to the first embodiment shown in FIG. 2 is configured as described below as similar to the PLL circuit according to the related art shown in FIG. 1. A phase comparator 1 calculates phase difference between a divided frequency fp of a feedback signal provided from a voltage controlled oscillator (VCO) 5 and a reference frequency fr of a reference signal. The phase comparator 1 provides a DOWN signal or an UP signal depending on the calculated phase difference to a charge pump 2. However, according to the characteristics of the present invention, a timer circuit 3 for switching charge pump current to be provided by the charge pump 2 between a predetermined large current and a predetermined small current based on serial data provided from the exterior is provided instead of the delay circuits (as in the PLL circuit according to the related art) where the charge pump current to be provided by the charge pump 2 is switched between a predetermined large current and a predetermined small current after a predetermined delay time has elapsed. The charge pump 2 is connected to the VCO 5 via a low pass filter (LPF) 4.

The phase comparator 1 receives the divided frequency fp derived from the feedback signal provided from the VCO 5 via a comparison frequency divider circuit 61 and the reference frequency fr derived from the reference signal provided from a crystal oscillator, etc. (not shown) via a reference frequency divider circuit 61. When the phase of the divided frequency fp is advanced with respect to the phase of the reference frequency fr, the phase comparator 1 provides the UP signal, which falls when the reference frequency fr falls and which rises when the divided frequency fp falls (see FIG. 3A). When the phase of reference frequency fr is advanced with respect to the phase of the divided frequency fp, the phase comparator 1 provides the DOWN signal, which falls when the divided frequency fp falls and which rises when the reference frequency fr falls (see FIG. 3B). The phase comparator 1 provides neither the UP signal nor the DOWN signal when the reference frequency fr and the divided frequency are in phase (see FIG. 3C).

The charge pump 2 is provided with switching portions 25, 26, which are switched between large constant current generators 21, 23 that provide a predetermined large charge pump current and a predetermined small constant current generators 22, 24 that provide a small charge pump current, respectively. These switching portions 25, 26 are switched based on a switching time set in the timer circuit 3. Further, the charge pump 2 is provided with a P-channel MOS 27 to receive the DOWN signal provided from the phase comparator 1 at its gate electrode and a N-channel MOS 28 to receive the UP signal provided from the phase comparator 1 and having a value inverted by an inverter (not shown) at its gate electrode. The charge pump 2 provides current to the LPF 4 based on the DOWN signal or the UP signal.

The timer circuit 3 is a switching timing control unit that uses delay time generated by dividing the frequency of the reference signal as the switching time and, when a reset signal is provided, switches the switching portions 25, 26 to the large constant current generators 21, 23 so as to provide the predetermined large current during the switching time, and switches the switching portions 25, 26 to the small constant current generators 22, 24, after the switching time has elapsed, so as to provide the predetermined small current. For example, the timer circuit 3, as shown in FIG. 4, includes a number of flip-flop circuits FF 1, FF 2, FF 3, FF 4, and a number of NAND circuits NAND 1, NAND 2 forming a frequency division circuit. The timer circuit 3 receives the reference signal as a clock signal, a load enable signal (LE) in the serial data provided from the exterior as a reset signal, a strobe signal (STB) in the serial data provided from the exterior as a counter set value, and timing control signals (TM 1, TM 2, and TM 3) in the serial data provided from the exterior as D inputs for respective flip-flop circuits FF 1, FF 2, and FF 3. The switching time depends on TM 1, TM 2, and TM 3 as shown in FIG. 5 and STB. For example, when TM 1 is set to 1, TM 2 to 0, and TM 3 to 0, only the flip-flop circuit FF 1 is effective and 1 cycle-period of the reference signal is generated. When TM 1 is set to 0, TM 2 to 1, and TM 3 to 0, only the flip-flop circuit FF 2 is effective and 2 cycle-periods of the reference signal are generated. When TM 1 is set to 1, TM 2 to 1, and TM 3 to 1, all the flip-flop circuits FF 1, FF 2, and FF 3 are effective and thus 7 cycle-periods of the reference signal are generated. The longest switching time is obtained when the values for TM 1, TM 2, and TM 3 are all set to 1 and the shortest switching time is obtained when TM 1 is set to 1, TM 2 to 0, and TM 3 to 0. However, as mentioned above, since this switching time also depends on the STB, longer switching time can be obtained by changing the value of the STB.

The following is a description of the operation of the PLL circuit according to the first embodiment of the present invention based on the above-mentioned configuration.

When the PLL circuit according to the first embodiment is activated, the crystal oscillator, etc. provides the reference signal and this reference signal is provided to the phase comparator 1 as the reference frequency fr via the reference frequency divider circuit 61. Also, the VCO 5 provides the feedback signal and this feedback signal is provided to the phase comparator 1 as the divided frequency fp via the comparison frequency divider circuit 62. When the reference frequency fr and the divided frequency fp are provided, the phase comparator 1 provides the DOWN signal or the UP signal to the respective gate electrodes of the P-channel MOS 27 and the N-channel MOS 28 according to the phase difference between the reference frequency fr and the divided frequency fp.

When the DOWN signal is provided from the phase comparator 1 to the charge pump 2, voltage of the DOWN signal is applied to the gate electrode of the P-channel MOS 27 and current corresponding to this voltage is applied to the LPF 4.

When the UP signal is provided from the phase comparator 1 to the charge pump 2, voltage of the UP signal is applied to the gate electrode of the N-channel MOS 28 and current corresponding to this voltage is applied to the LPF 4.

During a locked condition, a constant current is applied to the LPF 4 from the small constant current generators 22, 24 of the charge pump 2 with no changes to both the DOWN signal and the UP signal. The LPF 4 blocks a high frequency component of the voltage applied from the small constant current generators 22, 24. The VCO 5 receives the voltage having its high frequency component blocked via the LPF 4 and generates a signal having a predetermined oscillation frequency according to this input voltage, which is to be provided to the comparison frequency divider circuit 62.

The following is a description of the lock-up operation. The PLL circuit according to the first embodiment, which is in the locked condition, receives the serial data from the exterior when switching the lock frequency. The timer circuit 3 receives the load enable signal (LE) in the serial data as the reset signal. When the load enable signal (LE) is provided, the timer circuit 3 switches the switching portions 25, 26 so as to provide the predetermined large current from the charge pump 2 during the switching time determined by TM 1, TM 2, TM 3, and STB. After the switching time has elapsed, the timer circuit 3 switches the switching portions 25, 26 so as to provide the predetermined small current as in the locked condition.

During the switching time when the predetermined large current is provided from the charge pump 2 by the timer circuit 3, the varied DOWN signal or the varied UP signal from the phase comparator 1 is simultaneously provided to the charge pump 2 for switching the lock frequency, and the voltage corresponding to the varied DOWN signal or the varied UP signal is applied to the LPF 4 from the charge pump 2. The LPF 4 blocks the high frequency component of the voltage applied from the large constant current generators 21, 23 and the VCO 5 generates the signal having the target oscillation frequency so as to be in phase with the reference signal according to this input voltage, which is to be provided to the comparison frequency divider circuit 62. The lock-up operation ends and the locked condition is established again when neither the DOWN signal nor the UP signal is provided from the phase comparator 1 which indicates that the reference frequency fr and the divided frequency fp are in phase. It is noted that at least when the locked condition is established again, the timer circuit 3 has already switched the charge pump current to be provided to the voltage controlled oscillator via the low pass filter from the predetermined large current to the predetermined small current. Thus the charge pump 2 is providing the predetermined small current when the locked condition is established.

According to the PLL circuit of the first embodiment, since the timer circuit 3 switches the switching portions 25, 26 to the large constant current generators 21, 23 so as to provide the predetermined large current, which is provided to VCO 5 via the LPF 4, from the beginning of the lock-up operation and during the switching time based on the DOWN signal or the UP signal provided from the phase comparator 1, the VCO 5 can rapidly make the feedback signal in phase with the reference signal according to the provided current and the undershooting can be prevented. Therefore, it becomes possible to effectively reduce the required lock-up time. Also, since the time circuit 3 switches the switching portions 25, 26 from the large constant current generators 21, 23 to the small constant current generators 22,24 so as to provide the predetermined small current at least during the time interval between the beginning of the lock-up operation and the end of the lock-up operation or the time just before the end of the lock-up operation, the overshooting can be prevented and thus it is possible to stabilize the locked condition.

It is noted that in the PLL circuit according to the first embodiment of the present invention, the switching time can be changed based on the serial data provided from the exterior. However, it may be possible to fix the inputs of the flip-flop circuits of the timer circuit 3 and to configure the timer circuit 3 so as to switch the switching portions 25, 26 during a predetermined switching time without changing the switching time.

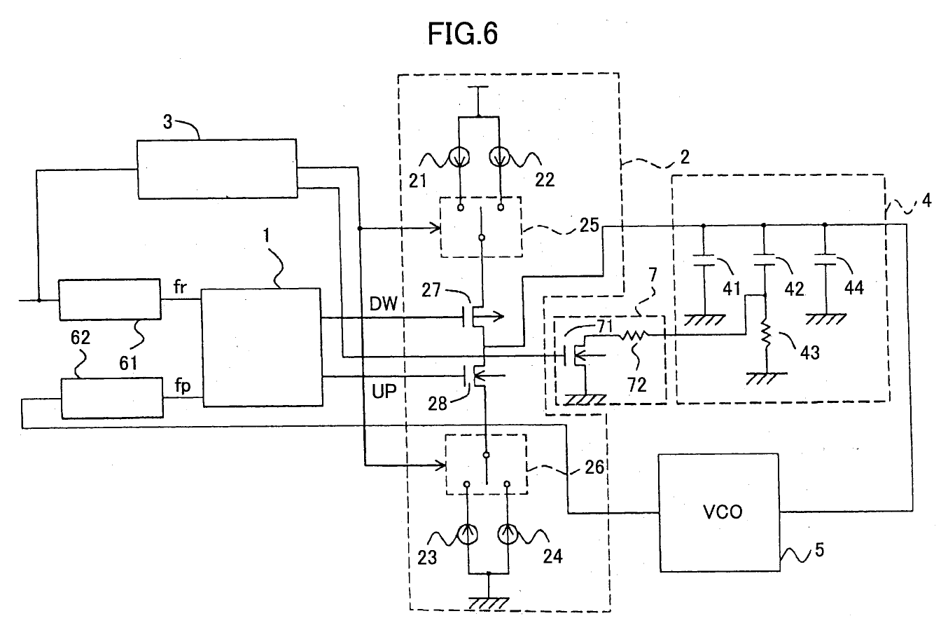

A description of a second embodiment of the present invention is given hereinafter with reference to FIG. 6. FIG. 6 is a diagram of an overall circuit configuration of the PLL circuit according to the second embodiment.

The PLL circuit according to the second embodiment shown in FIG. 6 is configured similar to the PLL circuit according to the first embodiment of the present invention shown in FIG. 2. In addition to the configuration of the first embodiment, the PLL circuit according to the second embodiment is provided with an impedance adjustment unit 7 for adjusting the impedance of the LPF 4 during the switching time of the timer circuit 3 and during other times.

The impedance adjustment unit 7 is provided with an N-channel MOS 71 receiving the output of the timer circuit 3 as an input at its gate electrode and a resistor 72 serially connected to the N-channel MOS 71. The impedance adjustment unit 7 is controlled by voltage applied to the gate electrode of the N-channel MOS 71 from the timer circuit 3.

The operation of the PLL circuit according to the second embodiment of the present invention is similar to that of the PLL circuit according to the first embodiment. However, in addition to the operation of the first embodiment, when the lock-up operation is started when the timer circuit 3 switches the switching portions 25, 26 to the large constant current generators 21, 23 so as to provide the predetermined large current during the switching time, the timer circuit 3 also changes the voltage provided to the gate electrode of the N-channel MOS 71 of the impedance adjustment unit 7 so as to make the resistor 72 effective for the LPF 4. The timer circuit 3 switches the switching portions 25, 26 to the small constant current generators 22, 24, after the switching time has elapsed, so as to provide the predetermined small current. The timer circuit 3 also changes the voltage provided to the gate electrode of the N-channel MOS 71 of the impedance adjustment unit 7 so as to make the resistor 72 ineffective for the LPF 4.

According to the PLL circuit of the second embodiment of the present invention, since the timer circuit 3 switches the switching portions 25, 26 to the large constant current generators 21, 23 so as to provide the predetermined large current from the beginning of the lock-up operation and during the switching time, and also since the timer circuit 3 changes the voltage provided to the impedance adjustment unit 7 so as to make the resistor 72 effective for the LPF 4, when the predetermined large current is provided to the LPF 4 from the charge pump 2, the LPF 4 has an impedance most appropriate for such predetermined large current and thus the lock-up operation can be performed more effectively.

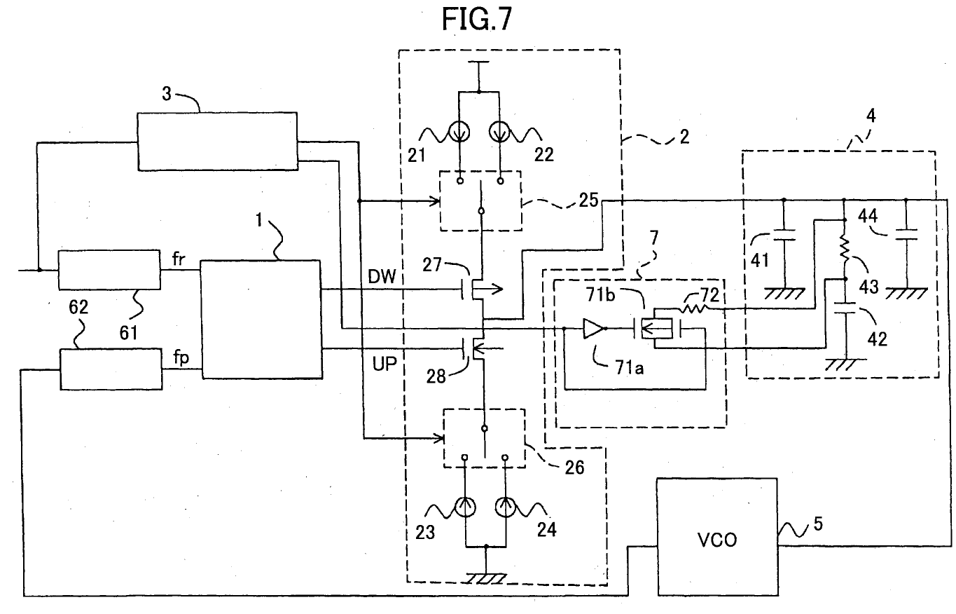

It is noted that in the PLL circuit according to the second embodiment of the present invention, a NOT circuit 71a and a transmission 71b may be used instead of the N-channel MOS 71 as shown in FIG. 7 so as to directly ground a capacitor 42 of the LPF 4 without the current passing by way of a resistor 43.

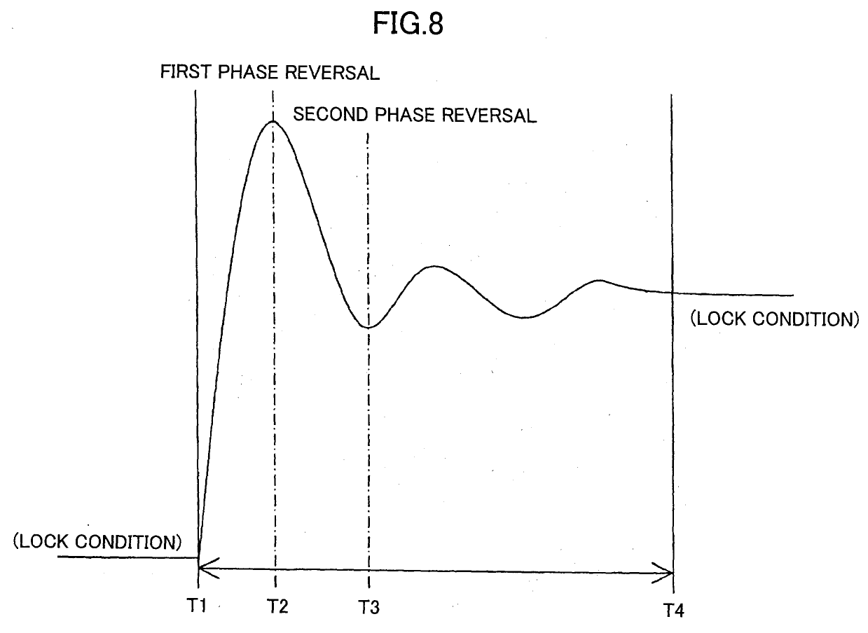

The following is a description of the PLL circuit according to another embodiment of the present invention with reference to FIG. 8.

The PLL circuit according to the first and the second embodiments of the present invention may be provided with a detection unit for detecting the time when the rate of change of the frequency of the feedback signal of the VCO 5 reverses from positive to negative so as to make the switching time shorter than the time interval between the beginning of the lock-up operation and the first reversal of the frequency of the feedback signal. By defining the switching time shorter than |T2−T1|, which is the above-mentioned time interval between T1, the beginning of the lock-up operation, and T2, the time of first reversal of the frequency, the timer circuit 3 switches the switching portions 25, 26 to the large constant current generators 21, 23 so as to provide the predetermined large current only during |T2−T1|. Therefore, the overshooting of the lock-up waveform can be effectively suppressed so as to reduce the required lock-up time and to improve the signal-to-noise ratio.

Further, the present invention is not limited to the above-described embodiments, and variations and modifications may be made without departing from the scope of the present invention.

The present application is based on Japanese priority application No. 2002-145303, filed on May 20, 2002, the entire contents of which are hereby incorporated by reference.

What is claimed is:

1. A phase-locked loop circuit comprising:
a voltage controlled oscillator;
a phase comparator detecting phase difference between a given reference signal and a feedback signal provided from said voltage controlled oscillator;
an input voltage control unit controlling input voltage to be provided to said voltage controlled oscillator according to the phase difference detected by said phase comparator;
a switching unit switching a value of the input voltage to be provided to said voltage controlled oscillator; and
a switching timing control unit controlling a switching timing of said switching unit based on the given reference signal; wherein
said voltage controlled oscillator controls a frequency of the feedback signal according to said input voltage provided from said input voltage control unit.

2. The phase-locked loop circuit as claimed in claim 1, wherein:
said switching timing control unit determines the switching timing of said switching unit also based on serial data provided from the exterior.

3. The phase-locked loop circuit as claimed in claim 1, said circuit further comprising:
an impedance adjustment unit for adjusting impedance of a low pass filter to be inserted between said input voltage control unit and said voltage controlled oscillator according to the control of said switching timing control unit.

4. The phase-locked loop circuit as claimed in claim 1, wherein:
said switching timing control unit determines the switching timing into a time before the time when a first phase reversal of the feedback signal with respect to the given reference signal occurs.

5. The phase-locked loop circuit as claimed in claim 1, wherein:
the switching timing is determined so that the input voltage having a predetermined large value is provided to said voltage controlled oscillator from the beginning of a lock-up operation and the input voltage having a predetermined small value is provided to said voltage controlled oscillator in the vicinity of the end of the lock-up operation.
